(19) United States
(12) Patent Application Publication
(10) Pub. No.: US 2020/0243574 A1
(43) Pub. Date: Jul. 30, 2020

(54) FLEXIBLE DISPLAY PANEL, MANUFACTURING METHOD THEREOF AND DISPLAY DEVICE

(71) Applicant: BOE TECHNOLOGY GROUP CO., LTD., Beijing (CN)

(72) Inventors: Hongwei TIAN, Beijing (CN); Yanan NIU, Beijing (CN); Zheng LIU, Beijing (CN); Yueping ZUO, Beijing (CN); Xiaowei XU, Beijing (CN)

(73) Assignee: BOE TECHNOLOGY GROUP CO., LTD., Beijing (CN)

(21) Appl. No.: 15/764,552

(22) PCT Filed: Oct. 13, 2017
(86) PCT No.: PCT/CN2017/106060

§ 371 Date: Mar. 29, 2018

(30) Foreign Application Priority Data
Feb. 28, 2017 (CN) 201710114786.3

(51) Int. Cl. H01L 27/12

(52) U.S. Cl. CPC H01L 27/1248; H01L 27/1262; H01L 27/1218

(57) ABSTRACT

A flexible display panel, a manufacturing method thereof and a display device are provided. The flexible display panel includes: a flexible substrate and an inorganic insulating layer(s) and an organic insulating layer on the flexible substrate. The inorganic insulating layer(s) is provided with a recess in a region to be bent of the flexible display panel. The organic insulating layer at least covers a surface of the recess, and the flexibility of the organic insulating layer is greater than that of the inorganic insulating layer(s).

### CROSS REFERENCE TO RELATED APPLICATIONS

The application claims priority to the Chinese patent application No. 201710114786.3, filed on Feb. 28, 2017 with SIPO and entitled “Flexible Display Panel, Manufacturing Method thereof and Display Device”, which is incorporated herein by reference in its entirety.

### TECHNICAL FIELD

Embodiments of the present disclosure relate to a flexible display panel, a manufacturing method thereof and a display device.

### BACKGROUND

Flexible devices are more and more widely applied in our lives. Flexible electronic devices, especially flexible display panels, have attracted more and more attention due to characteristics, such as lightness, thinness, flexibility, foldability and good mechanical properties. However, when being bent, as the flexible display panel adopts a large number of inorganic processes, the total thickness of the inorganic film layer is generally more than 1,000 nm. For example, it is more likely that cracks and even fractures occur in the inorganic film layer, such as SiNₓ, due to the impact of positive and negative stress when the inorganic film layer is bent frequently, resulting in a compromised quality and even damage and failure of the flexible display panel.

### SUMMARY

Embodiments of the present disclosure provide a flexible display panel, a manufacturing method thereof and a display device.

Embodiments of the present disclosure provide a flexible display panel, comprising: a flexible substrate; and inorganic insulating layer(s) and an organic insulating layer provided on the flexible substrate. The inorganic insulating layer(s) is/are provided with a recess in a region to be bent of the flexible display panel; and the organic insulating layer at least covers a surface of the recess.

Embodiments of the present disclosure provide a display device, comprising any of the flexible display panel.

Embodiments of the present disclosure provide a method of manufacturing any of the flexible display panel, comprising: forming the inorganic insulating layer(s) and the organic insulating layer on the flexible substrate; and forming the recess in the inorganic insulating layer(s) in the region to be bent of the flexible display panel, and allowing the organic insulating layer to at least cover a surface of the recess.

### BRIEF DESCRIPTION OF THE DRAWINGS

Embodiments of the present disclosure will be described in more detail below with reference to accompanying drawings to allow an ordinary skill in the art to more clearly understand embodiments of the present disclosure, in which:

FIGS. 1A-1C are basic schematic structural views of a flexible display panel provided by an embodiment of the present disclosure;

FIG. 2 is a schematically structural view of a flexible display panel with an organic insulating layer filling part of inorganic insulating layer(s) and space between the inorganic insulating layer(s) and a source-drain layer in an embodiment of the present disclosure;

FIG. 3A is a schematically structural view of a flexible display panel with an organic insulating layer filling entire inorganic insulating layer(s) and space between the inorganic insulating layer(s) and a source-drain layer in an embodiment of the present disclosure;

FIG. 3B is a schematically structural view of a flexible display panel provided with an additional film layer in an embodiment of the present disclosure;

FIG. 4 is a schematically structural view of a flexible display panel with an organic insulating layer filling a recess in an embodiment of the present disclosure;

FIG. 5A is a schematically structural view of a flexible display panel with a region to be bent being disposed in a non-display region of the flexible display panel in an embodiment of the present disclosure;

FIG. 5B is a schematically structural view of a flexible display panel with a region to be bent being disposed in a non-pixel region of the flexible display panel in an embodiment of the present disclosure;

FIG. 6 is a schematically structural view of a flexible display panel with inorganic insulating layer(s) in a region to be bent being completely removed in an embodiment of the present disclosure;

FIGS. 7A-7D are schematically structural views of flexible display panels with an additional film layer being disposed in a region to be bent in embodiments of the present disclosure;

FIG. 8 is a flow chart of a method for manufacturing a flexible display panel, provided by an embodiment of the present disclosure;

FIG. 9 is a flow chart illustrating a process of forming a recess and an organic insulating layer by photolithography in an embodiment of the present disclosure;

FIGS. 10A-10C are respectively schematically structural views illustrating structures obtained after operations in a process of forming a recess and an organic insulating layer by photolithography are executed in an embodiment of the present disclosure;

FIG. 11 is a flow chart illustrating a process of forming a recess and an organic insulating layer by a half-tone mask process in an embodiment of the present disclosure;

FIGS. 12A-12E are respectively schematically structural views illustrating structures obtained after operations in a process of forming a recess and an organic insulating layer by a half-tone mask process are executed in an embodiment of the present disclosure; and

FIG. 13 is a schematic plan view of a flexible display panel provided by an embodiment of the present disclosure.

### DETAILED DESCRIPTION

Technical solutions of the embodiments will be described in a clearly and fully understandable way in connection with the drawings related to the embodiments of the disclosure. It is apparent that the described embodiments are just a part but not all of the embodiments of the disclosure. Based on the described embodiments herein, those skilled in the art can obtain other embodiment(s), without any creative work, which shall be within the scope of the disclosure.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present disclosure, are not intended to indicate any sequence, amount or importance, but for distinguishing various components. The terms, such as “comprise/comprising,” “include/including,” or the like are intended to specify that the elements or the objects stated before these terms encompass the elements or the objects and equivalents thereof listed after these terms, but not preclude other elements or objects. The terms, “on,” “under,” or the like are only used to indicate relative position relationship, and when the position of the object which is described is changed, the relative position relationship may be changed accordingly.

The thickness of layers, the shape of regions, the features, the shape and the size of structures or the like in the accompanying drawings do not reflect a true scale and are only used for schematically illustrating the content of the present disclosure.

Embodiments of the present disclosure provide a flexible display panel. In a flexible display panel provided with a region to be bent frequently, a recess is formed in the region to be bent frequently of inorganic insulating layer(s); an organic insulating layer of which the flexibility is greater than that of the inorganic insulating layer(s) is arranged between the inorganic insulating layer(s) and a source-drain layer; and the organic insulating layer is allowed to at least cover or completely cover the recess in the region to be bent frequently. In this way, for those display panels which can be bent, they can adopt the structure(s) of the embodiments of the present disclosure.

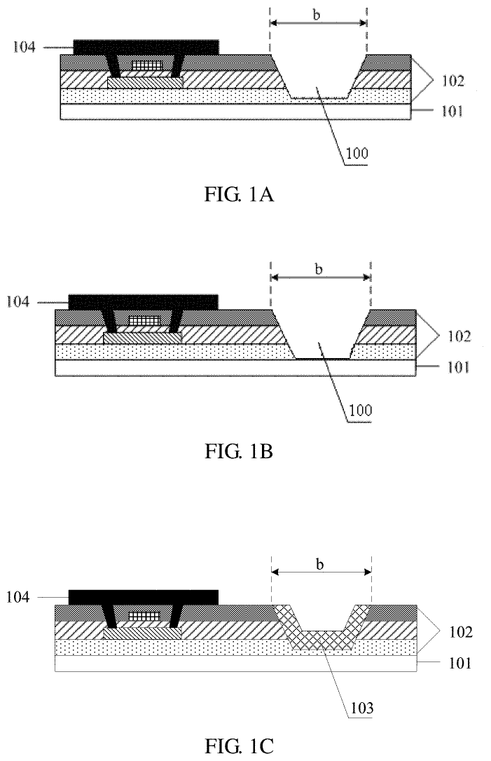

As shown in FIGS. 1A-1C which are basic schematic structural views of a flexible display panel provided by embodiment of the present disclosure. The flexible display panel comprises: a non-bending region (including a display region a) and a region to be bent frequently b.

For instance, the flexible display panel comprises a flexible substrate 101, inorganic insulating layer(s) 102 disposed on the flexible substrate 101, and a recess 100 formed in a region to be bent b. The flexible display panel may also comprise an organic insulating layer 103 and a source-drain layer 104. For instance, the organic insulating layer 103 at least completely covers a surface of the recess 100, and the flexibility of the organic insulating layer 103 is greater than that of the inorganic insulating layer(s) 102.

The flexible substrate, for instance, may be a plastic substrate.

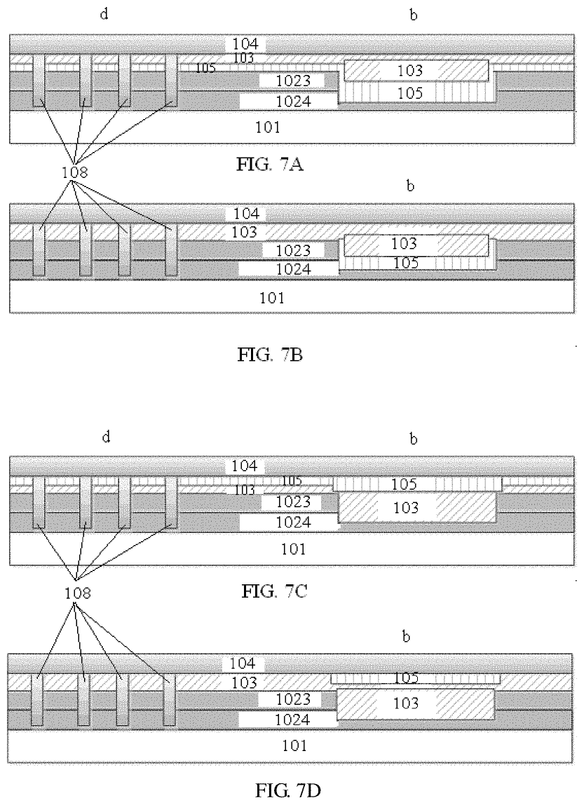

For instance, inorganic insulating layers 102, an organic insulating layer 103 and a source-drain layer 104 are disposed on a flexible substrate 101. The region to be bent b may be disposed in a non-display region of the flexible display panel and may be disposed in the display region. For instance, the region to be bent b is disposed in a corresponding region on the inorganic insulating layers not provided with through holes 108, namely a region except through-hole region d. The flexible display panel comprises the inorganic insulating layers 102, the organic insulating layer 103 and the source-drain layer 104, and it may also comprise other functional layers 1024 (not specifically shown for clarity), as shown in FIGS. 7A-7D.

As cracks and even fractures easily occur in inorganic insulating layer(s) of the flexible display panel due to frequently bending, in the flexible display panel provided by the embodiment of the present disclosure, the recess is formed in the region to be bent of the inorganic insulating layer(s); the organic insulating layer of which the flexibility is greater than that of the inorganic insulating layer(s) is additionally arranged; and the organic insulating layer is allowed to at least cover or completely cover the recess in the region to be bent. In this way, the inorganic layer(s) in the region to be bent is reduced, so as to prevent cracks and even fractures occurring in the inorganic layer(s) in the region to be bent due to frequently bending, avoid the damage of the stress to a device when it is bent, and improve the reliability and the service life of the device.

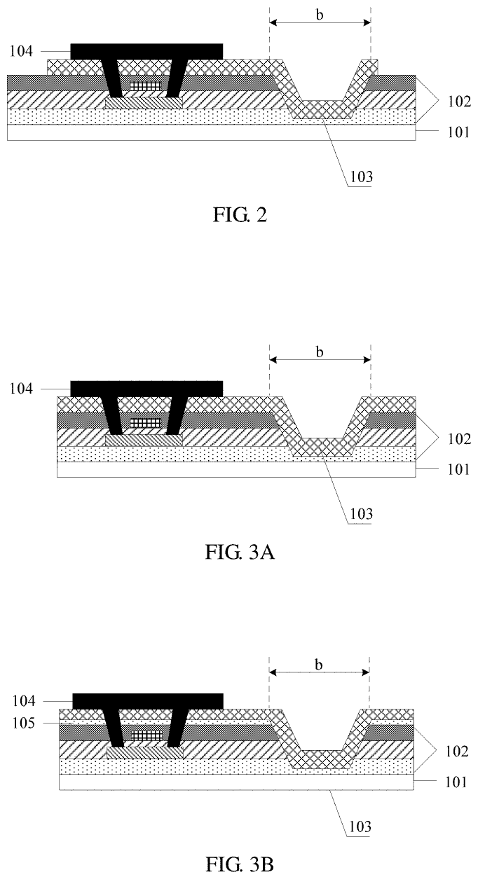

For instance, the organic insulating layer formed in the embodiment of the present disclosure may, as shown in FIG. 1C, completely cover the surface of the recess, and it is not provided in the space between the inorganic insulating layer(s) and the source-drain layer. The organic insulating layer may also be set to be able to fill the space between the inorganic insulating layer and the source-drain layer, namely the organic insulating layer may completely cover the inorganic insulating layer(s) 102, as shown in FIG. 2. Detailed description will be given below. In addition, the organic insulating layer may also be set to be able to fill the space between partial inorganic insulating layer(s) and the source-drain layer in addition to completely covering the surface of the recess, namely the organic insulating layer may partially cover the inorganic insulating layer(s) 102. However, the embodiment of the present disclosure is not limited thereto.

For the convenience of production, processes are not added. As shown in FIGS. 2-3A and 7A-7B, the organic insulating layer may be at least disposed on the periphery of the position of the recess and the positions used for forming the through holes of source/drain electrodes. The manufacturing method of the organic insulating layer may refer to the following manufacturing method of the flexible display panel.

In the embodiment of the present disclosure, the organic insulating layer with strong flexibility under a given bending radius is additionally arranged between the inorganic insulating layer(s) and the source-drain layer. The flexibility under the given bending radius refers to the ability of the material to resist stress without damage when the material is bent to a certain bending radius (generally small bending radius, detailed description will be given below). When the flexibility of the material under the given bending radius is higher, the material is less likely to create cracks and even fractures when being bent.

The structure in the embodiment of the present disclosure is mainly applied in the flexible display panel provided with fixed regions to be bent. The region to be bent is generally disposed in the non-pixel region. In order to prevent cracks and even fractures occurring in the inorganic insulating layer(s) in the region to be bent due to frequently bending, in the embodiment of the present disclosure, the recess is formed in the region to be bent of the inorganic insulating layer, and the organic insulating layer at least completely covers the surface of the recess.

For instance, the region to be bent on the flexible display panel may generally be divided into a main bending region and the remaining bending region. The main bending region refers to a region with small bending radius, e.g., with the bending radius of less than about 5 mm. The remaining bending region refers to a region with slight bending and large bending radius, e.g., with the bending radius of about 20 mm.

The bending radius of the region to be bent may be varied according to the design demands of products. As cracks and even fractures easily occur in the inorganic insulating layer(s) in the region with larger bending radius, the bending region in the embodiment of the present disclosure normally refers to the bending region with small bending radius, namely the main bending region, for instance, the bending region which has a given bending radius of less than 5 mm.

For instance, the flexible display panel provided by the embodiment of the present disclosure may also be a flexible display panel of other bending types besides the fixed region to be bent, e.g., a flexible display panel in which the entire display panel may be bent along a certain direction, and even may be a flexible display panel which can be randomly bent. In order to allow the organic insulating layer in the recess to have maximum protection function, the arrangement modes of the recess are also different for display panels of different bending types. For instance, for the flexible display panel comprises a fixed region to be bent, the lengthwise direction of the recess is set along the bending axial direction; for the flexible display panel which can be randomly bent, a circle of recess structure may be arranged around one or more luminous pixel regions and in a non-pixel region which does not emit light; or other structures may be designed, which shall not affect the normal display of the flexible display panel.

For instance, in the flexible display panel provided by an embodiment of the present disclosure, the organic insulating layer may also be filled a space between the inorganic insulating layer(s) and the source-drain layer in addition to completely covering the surface of the recess, and has a function of raising the formed spatial structure. For instance, the organic insulating layer is also filled a space between the source-drain layer and the inorganic insulating layer which is the closest to the source-drain layer.

As shown in FIG. 3A which is a schematic structural view illustrating a case that the organic insulating layer is filled a space between the entire inorganic insulating layer(s) and the source-drain layer in the embodiment of the present disclosure. In FIG. 3A, the organic insulating layer 103 covers the recess region on the inorganic insulating layer(s) and fills the space between the inorganic insulating layer on the upmost layer and the source-drain layer. That is to say, in this case, an orthographic projection of the organic insulating layer on the flexible substrate completely covers an orthographic projection of the inorganic insulating layer(s) on the flexible substrate.

For instance, as the organic insulating layer completely covers the inorganic insulating layer on the upmost layer, the organic insulating layer may have a function of raising the formed spatial structure with a certain thickness. Meanwhile, the organic insulating layer may replace partial inorganic insulating layer(s) by utilization of the insulating function of the organic insulating layer, and the thickness of the inorganic insulating layer on the upmost layer may be properly decreased in the preparing process. In addition, as the flexibility of the organic insulating layer under the given bending radius is greater than that of the inorganic insulating layer(s) under the given bending radius, the thickness of the inorganic insulating layer on the upmost layer is properly decreased, and the organic insulating layer is adopted to replace partial inorganic insulating layer(s), so the probability that cracks and even fractures occur in the inorganic insulating layer(s) due to frequent bending can be reduced, and the damage of the stress to the device when the device is bent can be reduced.

For instance, the material of the organic insulating layer is one or a combination of the following materials, such as polyimide type organic layer. In addition, other insulating layers with good flexibility may also be selected as the organic insulating layer, as long as the flexibility is greater than that of the inorganic insulating layer(s) under the given bending radius.

To further improve the flexibility of the organic insulating layer, material(s) with higher flexibility may be doped into the material of the organic insulating layer. For instance, flexible material is doped into the organic insulating layer. For instance, polyimide material(s) doped with grapheme, or polyimide material(s) doped with nano-ceramic(s) may be adopted to prepare the organic insulating layer.

In addition to the material(s) with higher flexibility may be directly doped into the formed organic insulating layer, a layer of material(s) with higher flexibility may be formed before the operation of forming the organic insulating layer. For instance, as shown in FIGS. 3B and 7A-7B, an additional film layer 105 is disposed on a side of the organic insulating layer 103 near the flexible substrate 101.

The flexibility of the material of the additional film layer 105 is greater than that of the material of the organic insulating layer 103. For instance, an orthographic projection of the additional film layer 105 on the flexible substrate 101 falls within the orthographic projection of the organic insulating layer 103 on the flexible substrate 101.

Without affecting the display function, the additional film layer 105 may be disposed in the entire region under the organic insulating layer 103 and may also be only disposed in a region under the organic insulating layer 103 except the recess, or may be only disposed in a region under the organic insulating layer 103 in the recess region. The orthographic projection of the additional film layer on the flexible substrate 101 also correspondingly falls within an orthographic projection of a corresponding part of the organic insulating layer 103 on the flexible substrate 101.

The organic insulating layer 103 may also be formed on the inorganic layer at first and then the additional film layer 105 may be formed on the organic insulating layer 103, as shown in FIGS. 7C-7D. In this example, the additional film layer 105 may be disposed in the entire region on the organic insulating layer 103, as shown in FIG. 7C; and may also be only disposed in the region on the organic insulating layer 103 formed by the recess region, or cover the organic insulating layer 103 in the recess region. For instance, the orthographic projection of the additional film layer 105 on the flexible substrate 101 falls within the orthographic projection of the organic insulating layer 103 on the flexible substrate 101; or the orthographic projection of the additional film layer 105 on the flexible substrate 101 is greater than or equal to the region of the orthographic projection of the recess region on the substrate 101. FIG. 3B is a schematically structural view of the flexible display panel provided with the additional film layer, provided by the embodiment of the present disclosure. For instance, as the added additional film layer has strong flexibility, the deformation of the inorganic insulating layer(s) is buffered, and, if the inorganic insulating layer(s) has/have crack(s), the additional film layer can properly prevent cracks from propagating upwards, so the size of the additional film layer 105 is not greater than that of the organic insulating layer, namely the region of the orthographic projection of the additional film layer 105 on the substrate 101 is not greater than the region of the orthographic projection of the organic insulating layer on the substrate 101. Without increasing the thickness of the flexible display panel, the thickness of the additional film layer is generally set to be 1,000 Å-8,000 Å.

In the process of forming the additional film layer, material with strong flexibility may be selected. For instance, the material of the additional film layer is one or a combination of the following materials: material which is the same as the material of the organic insulating layer and doped with graphene, material which is the same as the material of the organic insulating layer and doped with nano-ceramic, or graphene.

For instance, the thickness of the organic insulating layer filled between the inorganic insulating layer(s) and the source-drain layer is 0.5 μm-2 μm; and the thickness of the organic insulating layer covering the surface of the recess is 0.5 μm-3 μm.

For instance, in the structure as shown in FIG. 3A, in the recess 100 in the region to be bent b, the organic insulating layer 103 only covers the surface of the recess and is not entirely filled into the recess 100. In addition, without affecting other functional layers formed on the organic insulating layer 103, the organic insulating layer 103 may also entirely fill the recess 100, namely forming a structure as shown in FIG. 4, in which the organic insulating layer 103 entirely fills the recess 100. In addition, the organic insulating layer 103 may also be several micrometers to tens micrometers, e.g., 3-30 μm, higher than the horizontal level of the recess after it entirely fills the recess 100. The inventor(s) has noticed that this filling way of the organic insulating layer may obtain better anti-bending effect.

Description will be given in the following embodiments by taking the arrangement mode of the organic insulating layer in FIG. 3A as an example.

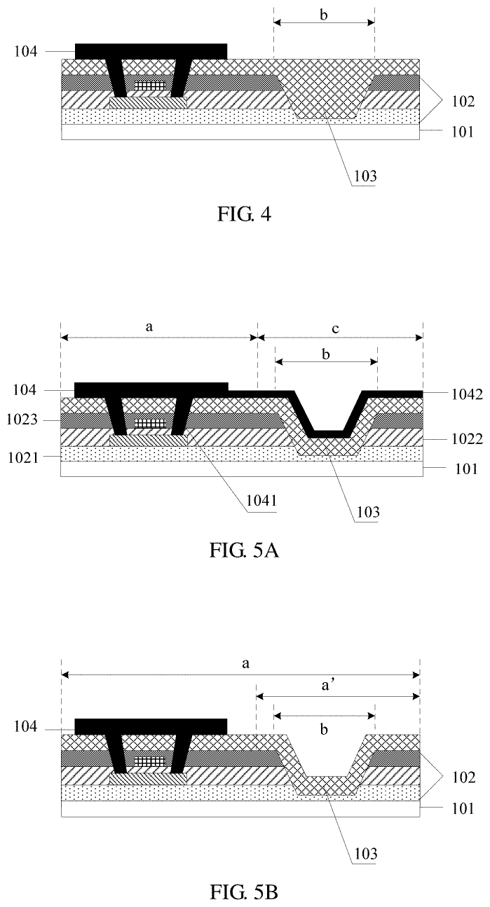

FIG. 5A is a schematically structural view of the flexible display panel with the region to be bent b being disposed in the non-display region of the flexible display panel in an embodiment of the present disclosure. Letter a in the figure represents the display region; b represents the region to be bent; and c represents the non-display region. For instance, the source-drain layer 104 includes: source/drain electrodes 1041 and source/drain leads 1042 connected with the source/drain electrodes 1041; the region to be bent is disposed in the non-display region c of the flexible display panel; and the recess 100 is formed under the source-drain lead 1042.

For instance, as shown in FIGS. 7A-7D and 13, a through-hole region d is arranged in a non-bending region.

For instance, when the region to be bent b is arranged in the non-display region on the border of the flexible display panel, namely when the recess 100 on the inorganic insulating layer(s) 102 or the flexible substrate 101 is disposed in the non-display region, as the leads 1042 of the source/drain electrodes will generally run through the region to be bent, an organic insulating layer with strong flexibility under the given bending radius is added between the inorganic layer on the upmost layer and the source-drain layer, so as to prevent cracks and even fractures occurring in the source/drain leads due to frequent bending.

In addition, in the flexible display panel provided by an embodiment of the present disclosure, when the region to be bent is disposed in the non-display region on the border of the flexible display panel, the number of the main bending regions with the bending radius of not greater than 5 mm is generally 1 or 2, and each region to be bent is provided with a recess structure correspondingly.

When the region to be bent is disposed in the display region, the region shall be kept away from a luminous region as much as possible for the convenience of production. FIG. 5B is a schematically structural view illustrating an instance that the region to be bent is disposed in the non-pixel region of the flexible display panel in the embodiment of the present disclosure. For instance, the region to be bent b is disposed in the display region a of the flexible display panel; and the recess is disposed in a non-pixel region a′ in the display region a. For instance, the recess may be disposed in non-pixel region a′ without light emitting between adjacent subpixels.

For instance, the inorganic insulating layer(s) in the embodiment of the present disclosure may include a plurality of layers. For instance, as shown in FIG. 5A, the inorganic insulating layer(s) include(s): a buffer layer 1021, a gate insulating layer 1022 and an interlayer insulating layer 1023 which are sequentially arranged.

For instance, as shown in FIGS. 7A-7D, the flexible display panel provided by the embodiment(s) of the present disclosure may also comprise other layers 1024 under the interlayer insulating layer 1023.

For instance, the recess disposed in the region to be bent in the inorganic insulating layer(s) may be, as shown in FIGS. 1-5B, set to allow the bottom of the recess 100 to be a certain distance from the flexible substrate 101. For instance, the thickness of the bottom of the recess is 50 Å-1,000 Å.

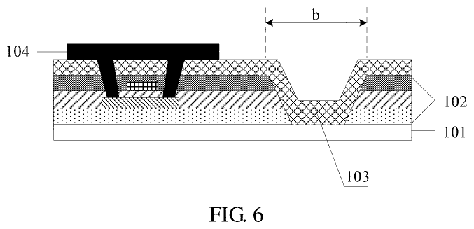

For instance, the inorganic insulating layer(s) in the region to be bent may also be completely removed, namely being removed to the upper part of the flexible substrate. FIG. 1B is a schematically structural view illustrating a case that the inorganic insulating layer(s) in the region to be bent is/are completely removed in the embodiment of the present disclosure. Subsequently, the organic insulating layer is disposed in the recess 100, as shown in FIG. 6. However, the embodiment of the present disclosure is not limited thereto.

For instance, for the recess 100 disposed in the region to be bent in the inorganic insulating layer(s), the width of the recess opening generally depends on the bending radius. For instance, the width of the recess is 0.5 mm-5 mm. Moreover, for instance, the width of the recess is about 0.5 mm.

For instance, the flexible display panel provided by the embodiments of the present disclosure may be rectangular or may be other abnormal shapes of display panels required to be bent. In addition, FIGS. 1-7 are only schematic diagrams illustrating the structure of the flexible display panel and not intended to limit the real structure of the flexible display panel. The thickness of the layers, the number of the source-drain electrodes, the position of other layers and the like may be set according to actual demands. For instance, the organic insulating layer may also be disposed at other positions without affecting the function(s), for instance, under the inorganic insulating layer(s).

Based on the same concept, the embodiment of the present disclosure also provides a display device, which comprises any foregoing flexible display panel provided by the embodiments of the present disclosure. As the principles of the display device in solving problems are similar to those of the flexible display panel provided by the embodiments of the present disclosure, implementation of the display device may refer to the implementation of the flexible display panel. No repeated description will be given herein.

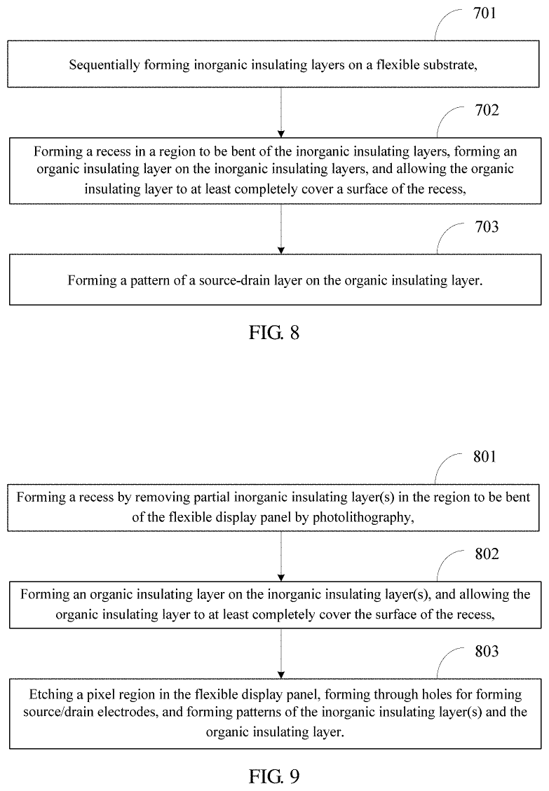

Based on the same concept, the embodiment of the present disclosure also provides a method for manufacturing a flexible display panel, which is used for manufacturing the flexible display panel provided by the embodiments of the present disclosure. As shown in FIG. 8, the following operations may be performed to manufacture the flexible display panel:

S701: sequentially forming inorganic insulating layers on a flexible substrate;

S702: forming a recess in a region to be bent of the inorganic insulating layer(s), forming an organic insulating layer on the inorganic insulating layer(s), and allowing the organic insulating layer to at least completely cover the surface of the recess; and

S703: forming a pattern of a source-drain layer on the organic insulating layer.

The flexibility of the organic insulating layer under a given bending radius is greater than that of the inorganic insulating layer(s) under the given bending radius.

Description will be given below to the example processes of forming the recess and the organic insulating layer.

Process of Forming the Recess and the Organic Insulating Layer by Photolithography

For instance, as shown in FIG. 9 which is a flow chart illustrating the process of forming the recess and the organic insulating layer by photolithography, the process includes:

S801: forming the recess by removing partial inorganic insulating layer(s) in the region to be bent of the flexible display panel by photolithography;

S802: forming the organic insulating layer on the inorganic insulating layer(s), and allowing the organic insulating layer to at least completely cover the surface of the recess; and

S803: etching the pixel region in the flexible display panel, forming through holes for preparing the source-drain electrodes, and forming patterns of the inorganic insulating layer(s) and the organic insulating layer.

Detailed description will be given below to the operations of forming the recess and the organic insulating layer by photolithography by taking the case of forming the flexible display panel with the structure in FIG. 3A as an example.

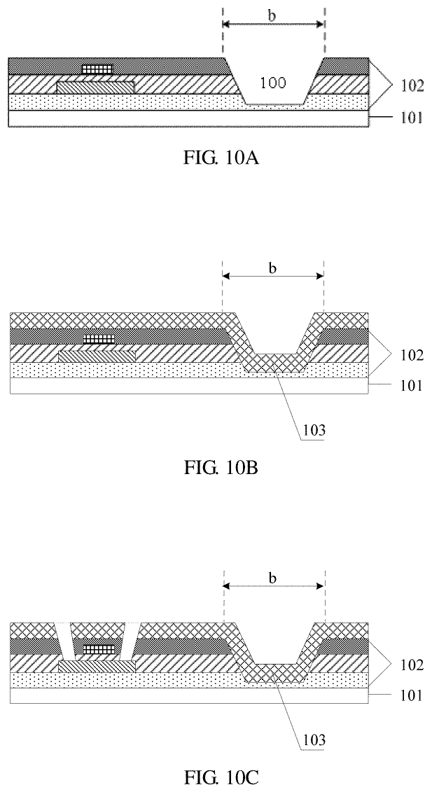

For instance, in the process of implementing the operation S801, as shown in FIG. 10A, one recess is formed by removing partial or entire inorganic insulating layer(s) by photolithography in the region to be bent b of the flexible display panel. The parameters of the recess may refer to the description on the flexible display panel. No repeated description will be given herein.

For instance, in the process of implementing the operation S802, as shown in FIG. 10B, the organic insulating layer is formed on the organic insulating layer and allowed to at least completely cover the surface of the recess. The approaches of forming the organic insulating layer include, inkjet printing, spin-coating, slit-coating, printing, or the like, for example. The thickness of the organic insulating layer, the coverage and the like may refer to the description on the flexible display panel. No repeated description will be given herein.

For instance, in the process of implementing the operation S803, as shown in FIG. 10C, after the operation of forming the organic insulating layer, through holes 108, which are, for instance, used for preparing the source-drain electrodes, are formed by etching the pixel region in the flexible display panel, and the patterns of the inorganic insulating layer(s) and the organic insulating layer are formed.

The structures formed in the process of manufacturing the flexible display panel as shown in FIGS. 1-2 and 4-7 are similar to those formed as shown in FIG. 3A. The structures obtained may refer to the structures after the operations in the process of forming the recess and the organic insulating layer by photolithography, as shown in the above schematic diagrams.

Process of Forming the Recess and the Organic Insulating Layer by a Half-tone Mask Process

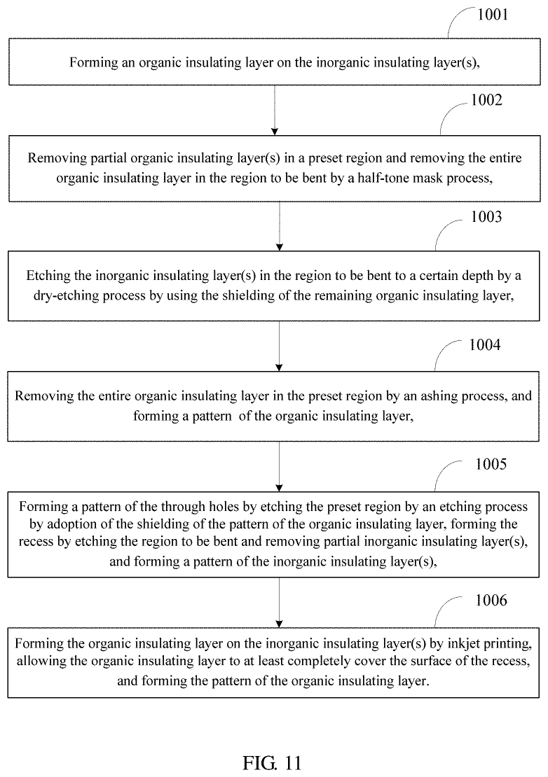

As shown in FIG. 11 which is a flow chart illustrating the process of forming the recess and the organic insulating layer by a half-tone mask process, the process includes:

S1001: forming the organic insulating layer on the inorganic insulating layer(s);

S1002: removing partial organic insulating layer in a preset region and removing the entire organic insulating layer in the region to be bent by a half-tone mask process, in which the preset region is used for forming the through holes of the source-drain electrodes on the inorganic insulating layer(s);

S1003: etching the inorganic insulating layer(s) in the region to be bent to a certain depth by a dry-etching process by adoption of the remaining organic insulating layer as a mask;

S1004: removing the entire organic insulating layer in the preset region by an ashing process, and forming a pattern of the organic insulating layer;

S1005: forming a pattern of the through holes by etching the preset region through an etching process with the pattern of the organic insulating layer as a mask, forming the recess by etching the region to be bent and removing partial inorganic insulating layer(s), and forming a pattern of the inorganic insulating layer(s); and

S1006: forming the organic insulating layer on the inorganic insulating layer(s) by inkjet printing, allowing the organic insulating layer to at least completely cover the surface of the recess, and forming the pattern of the organic insulating layer.

Detailed description will be given below to the operations of forming the recess and the organic insulating layer via a half-tone mask process by taking the case of forming the flexible display panel with the structure in FIG. 3A as an example.

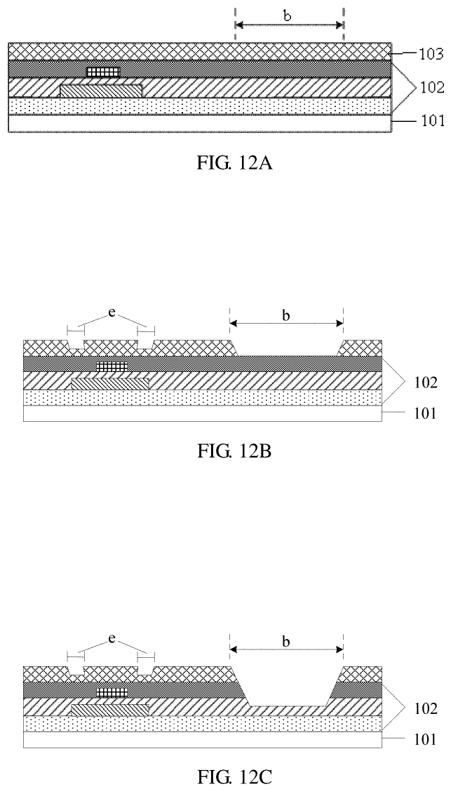

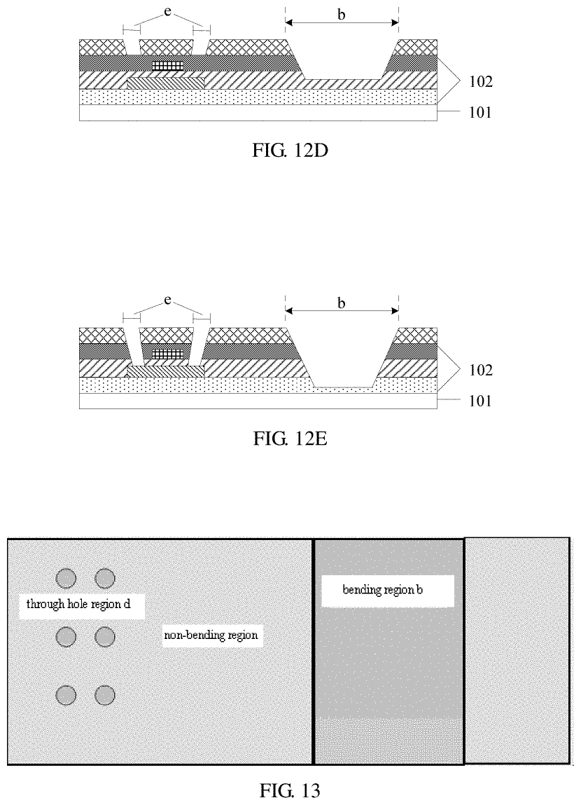

For instance, in the process of implementing the operation S1001, after the operation of forming the inorganic insulating layer(s), the through holes are not etched, instead, the organic insulating layer is formed on the inorganic insulating layer(s) at first to form the structure as shown in FIG. 12.

For instance, in the process of executing the operation S1002, the organic insulating layer on the upmost layer is etched by a half-tone mask process, and the entire organic insulating layer in the region to be bent b is removed when the upper part of the organic insulating layer in a preset region e is removed. The position of the preset region e is used for forming the through holes 108 of the source-drain electrode on the inorganic insulating layer(s), so as to form the structure as shown in FIG. 12B.

For instance, in the process of implementing the operation S1003, after the operation S1002 is executed, the inorganic insulating layer(s) in the region to be bent is continuously etched to a certain depth by a dry-etching process or other proper processes via the shielding of the remaining organic insulating layer. The recess structure is not etched completely at this operation, instead, it is completely etched in the operation S1005 to form the structure as shown in FIG. 12C.

For instance, in the process of executing the operation S1004, after the operation S1003, the remaining organic insulating layer in the preset region e is completely removed by an ashing process, and at this point, the pattern of the organic insulating layer is formed, namely forming the structure as shown in FIG. 12D.

For instance, in the process of implementing the operation S1005, when the complete pattern of the through holes is formed by etching the preset regions e by an etching process via the shielding of the pattern of the organic insulating layer, the region to be bent is continuously etched, and partial inorganic insulating layer(s) is removed to form the pattern of the recess. In this way, the pattern of the inorganic insulating layer(s) is formed, and the structure as shown in FIG. 12E is formed.

For instance, in the process of implementing the operation S1006, the organic insulating layer may be mainly formed in the recess region on the inorganic insulating layer(s) by inkjet printing and is allowed to at least completely cover the surface of the recess, and the pattern of the organic insulating layer is formed, that is, the structure as shown in FIG. 10C is formed.

In the two processes of forming the recess and the organic insulating layer, the organic insulating layer can be directly formed, a further improvement may also be made on this basis. For instance, material(s) with stronger flexibility is/are doped into the organic insulating material, or an additional layer 105 with stronger flexibility is formed before or after the operation of forming the organic insulating layer.

For instance, the operation of forming the organic insulating layer on the inorganic insulating layer(s) includes: forming the organic insulating layer doped with flexible material(s) on the inorganic insulating layer(s). For instance, a mixed solution which is uniformly mixed may be prepared in advance, and the mixed solution is an organic insulating material doped with the flexible material(s); the mixed solution is coated on the inorganic insulating layer(s); and finally the organic insulating layer doped with the flexible material(s) is formed. But the uniformity of the doped material(s) must be guaranteed in the manufacturing process, and the formed organic insulating layer may still be formed by the above two processes of forming the recess and the organic insulating layer, without affecting normal functions of other layers.

For instance, the operation of forming the organic insulating layer on the inorganic insulating layer(s) includes: forming an additional film layer on the inorganic insulating layer(s), and forming the organic insulating layer on the additional film layer. Optionally, the forming sequences of the additional film layer and the organic insulating layer may be opposite, namely forming the structure as shown in FIG. 3B, 7A-7B or 7C-7D; or the additional film layer is respectively formed on the two opposite surfaces of the organic insulating layer. The flexibility of the material of the additional film layer is greater than that of the material of the organic insulating layer. The flexible display panel provided with the additional film layer may be prepared by the above two preparing processes and the process flow is similar, and the additional film layer is formed before or after the operation of forming the organic insulating layer. The manufacturing process may refer to the description on the above two methods, so no repeated description will be given here to the manufacturing process.

The manufacturing process of other flexible display panel structures as shown in FIGS. 1-7 may refer to the process operations of forming the recess and the organic insulating layer by a half-tone mask process. No repeated description will be given here.

In the method for manufacturing the flexible display panel, provided by the embodiment of the present disclosure, in the process of forming the recess and the organic insulating layer by photolithography, the inorganic insulating layer(s) in the region to be bent is removed by using a mask, and subsequently, the organic insulating layer is coated on the interlayer insulating layer and the through holes of the source-drain electrodes in the display region are etched by using the organic insulating layer as a mask. In the process of forming the recess and the organic insulating layer by a half-tone mask process, the through holes of the source-drain electrodes in the display region may be etched when the inorganic insulating layer(s) in the region to be bent is etched by a half-tone mask process and an ashing process after the operation of forming the entire organic insulating layer, and subsequently, the organic insulating layer which at least completely covers the surface of the recess is formed in the recess in the region to be bent.

In the flexible display panel provided by the embodiments of the present disclosure, the recess is disposed in the region to be bent of the inorganic insulating layer(s); the organic insulating layer, of which the flexibility under the given bending radius is greater than that of the inorganic insulating layer(s), is added; the organic insulating layer is allowed to at least cover or completely cover the recess in the region to be bent; and the inorganic layer(s) in the region to be bent is reduced. In this way, cracks and even fractures are prevented from occurring in the inorganic layer(s) in the region to be bent due to frequent bending, which can avoid the damage of the stress to the device when the device is bent, and improve the reliability and the service life of the device. In addition, as the organic insulating layer may also completely cover the inorganic insulating layer on the upmost layer (e.g., the interlayer insulating layer), the organic insulating layer may replace the function of partial inorganic insulating layer(s) by utilization of the insulating function thereof. In this way, the thickness of the inorganic insulating layer on the upmost layer can be properly reduced in the manufacturing process.

The following points should be noted:

(1) The accompanying drawings in the embodiments of the present disclosure only involve structures relevant to the embodiments of the present disclosure, and other structures may refer to a common design.

(2) For clarity, in the accompanying drawings of the embodiments of the present disclosure, the thickness of layers or regions is enlarged or reduced. That is, the accompanying drawings are not drawn according to actual scales.

(3) Without conflict, the embodiments of the present disclosure and the features in the embodiments can be combined with each other to obtain new embodiments.

The described above are only exemplary embodiments of the present disclosure, and the present disclosure is not intended to be limited thereto. For one of ordinary skill in the art, various changes and alternations may be readily contemplated without departing from the technical scope of the present disclosure, and all of these changes and alternations shall fall within the scope of the present disclosure.

1. A flexible display panel, comprising:
a flexible substrate; and
inorganic insulating layer(s) and an organic insulating layer provided on the flexible substrate, wherein
the inorganic insulating layer(s) is/are provided with a recess in a region to be bent of the flexible display panel; and
the organic insulating layer at least covers a surface of the recess.

2. The flexible display panel according to claim 1, wherein the flexibility of the organic insulating layer is greater than that of the inorganic insulating layer(s).

3. The flexible display panel according to claim 1, wherein the organic insulating layer is disposed on a side of the inorganic insulating layer(s) away from the flexible substrate.

4. The flexible display panel according to claim 1, comprising an additional film layer disposed between the organic insulating layer and the inorganic insulating layer(s), and contacting the inorganic insulating layer(s) or the organic insulating layer directly.

5. (canceled)

6. The flexible display panel according to claim 4, wherein the additional film layer is disposed on a side of the inorganic insulating layer(s) away from the flexible substrate, or disposed on a side of the organic insulating layer away from the flexible substrate and at least covers a portion of the organic insulating layer in the recess.

7. (canceled)

8. The flexible display panel according to claim 1, wherein a portion of the organic insulating layer disposed in the recess is higher than the horizontal level of the recess.

9. The flexible display panel according to claim 1, further comprising: a source-drain layer formed on the flexible substrate; and through holes formed in non-bending regions of the flexible display panel, wherein the source-drain layer is disposed in the non-bending region; and the organic insulating layer is disposed between the inorganic insulating layer(s) and the source-drain layer.

10. (canceled)

11. The flexible display panel according to claim 1, wherein the inorganic insulating layer(s) is/are disposed on a side of the organic insulating layer away from the flexible substrate, and the organic insulating layer includes flexible material.

12. (canceled)

13. The flexible display panel according to claim 4, wherein material of the additional film layer is one or a combination of following materials:
material being the same as that of the organic insulating layer and doped with graphene, and material being the same as that of the organic insulating layer and doped with nano-ceramic, or graphene.

14. The flexible display panel according to claim 9, wherein the source-drain layer includes: source/drain electrodes and source/drain leads connected with the source/drain electrodes; and
the organic insulating layer is disposed between the source/drain leads and the inorganic insulating layer(s).

15. The flexible display panel according to claim 1, wherein the inorganic insulating layer(s) include(s): a buffer layer, a gate insulating layer and an interlayer insulating layer, which are sequentially arranged on the flexible substrate.

16. The flexible display panel according to claim 1, wherein material of the organic insulating layer is one or a combination of following materials:
polyimide and acrylic.

17. A display device, comprising the flexible display panel according to claim 1.

18. A method of manufacturing the flexible display panel according to claim 1, comprising:
forming the inorganic insulating layer(s) and the organic insulating layer on the flexible substrate; and
forming the recess in the inorganic insulating layer(s) in the region to be bent of the flexible display panel, and allowing the organic insulating layer to at least cover a surface of the recess.

19. The method of manufacturing the flexible display panel according to claim 18, further comprising: forming a pattern of the source-drain layer on the organic insulating layer, wherein the flexibility of the organic insulating layer is greater than that of the inorganic insulating layer(s).

20. The method according to claim 19, further comprising:
forming the recess by removing partial inorganic insulating layer(s) in the region to be bent of the flexible display panel by photolithography;
forming the organic insulating layer on the inorganic insulating layer(s), and allowing the organic insulating layer to at least cover the surface of the recess; and
etching a pixel region in the flexible display panel, forming through holes for forming the source/drain electrodes, and forming patterns of the inorganic insulating layer(s) and the organic insulating layer.

21. The method according to claim 18, further comprising:
forming the organic insulating layer on the inorganic insulating layer(s);
removing partial organic insulating layer in a preset region and removing an entire organic insulating layer in the region to be bent by half-tone mask process, in which through holes of source-drain electrodes are formed in the preset region on the inorganic insulating layer(s);
etching the inorganic insulating layer(s) in the region to be bent to a certain depth by dry-etching process by utilization of the shielding of the remaining organic insulating layer;
removing the entire organic insulating layer in the preset region by an asking process, and forming a pattern of the organic insulating layer;
forming a pattern of the through holes by etching the preset region by an etching process by adoption of the pattern of the organic insulating layer as an outer mask, forming the recess by etching the region to be bent and removing partial inorganic insulating layer(s), and forming a pattern of the inorganic insulating layer(s); and
forming the organic insulating layer on the inorganic insulating layer(s) by inkjet printing, allowing the organic insulating layer to at least cover the surface of the recess, and forming a pattern of the organic insulating layer.

22. The method according to claim 20, further comprising:
forming the organic insulating layer doped with flexible material on the inorganic insulating layer(s) by an inkjet printing.

23. The method according to claim 20, further comprising:
forming an additional film layer on the inorganic insulating layer(s); and
forming the organic insulating layer on the additional film layer, wherein
the flexibility of the material of the additional film layer is greater than that of the material of the organic insulating layer.

24. The method according to claim 20, further comprising:
forming an additional film layer on the organic insulating layer, and allowing the additional film layer to at least cover a portion of the organic insulating layer in the recess, wherein
the flexibility of the material of the additional film layer is greater than that of the material of the organic insulating layer.
